(19) United States
(12) Patent Application Publication
(10) Pub. No.: US 2025/0096219 A1
(43) Pub. Date: Mar. 20, 2025

(54) Inductive Heatable Particles in Semiconductor Module

(71) Applicant: Infineon Technologies AG, Neubiberg (DE)

(72) Inventors: Fabian Jaeger, Bestwig (DE); Jens Krugmann, Paderborn (DE)

(21) Appl. No.: 18/368,302

(22) Filed: Sep. 14, 2023

(51) Int. Cl. H01L 25/00; H01L 23/00; H01L 23/08; H01L 23/10; H01L 23/29; H01L 25/11; H01L 25/18

(52) U.S. Cl. CPC H01L 25/50; H01L 23/08; H01L 23/10; H01L 23/295; H01L 23/296; H01L 25/115; H01L 25/18; H01L 24/48; H01L 2224/48091; H01L 2224/48225

(57) ABSTRACT

A method of producing a semiconductor module includes providing a power module assembly that includes a floor section, a housing that encloses an interior volume over the floor section, and a power semiconductor die mounted to a power electronics carrier within the interior volume, filling the interior volume with a potting compound, providing inductive heatable particles within the power module assembly, and inductively heating the inductive heatable particles to activate and/or accelerate a chemical reaction in the potting compound.

### BACKGROUND

Many different applications such as automotive and industrial applications utilize power modules. Power modules may include multiple power semiconductor devices in a single package, with these power semiconductor devices being arranged as a power conversion circuit such as a single or multi-phase half-wave rectifier, single or multi-phase full-wave rectifier, voltage regulator, inverter, etc. Many applications that utilize power modules require the module to be capable of withstanding harsh environmental conditions, e.g., substantial temperature variation, moisture, etc. For this reason, power modules may include an electrically insulating encapsulant that protects and electrically isolates the circuitry within the power module. There is a need to improve upon the process that forms the electrically insulating encapsulant.

### SUMMARY

A method of producing a semiconductor module is disclosed. According to an embodiment, the method comprises providing a power module assembly that comprises a floor section, a housing that encloses an interior volume over the floor section, and a power semiconductor die mounted to a power electronics carrier within the volume, filling the interior volume with a potting compound that, providing inductive heatable particles within the power module assembly, and performing a curing process comprises inductively heating the inductive heatable particles.

A semiconductor module is disclosed. According to an embodiment, the semiconductor module comprises a floor section, a housing that encloses an interior volume over the floor section, a power semiconductor die mounted to a power electronics carrier within the interior volume, a potting compound within the interior volume, and inductive heatable particles, wherein the inductive heatable particles are either within the potting compound or are within a structure that is thermally coupled to the potting compound.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1, which includes FIGS. 1A and 1B, illustrates a power semiconductor module, according to an embodiment. FIG. 1A illustrates the power semiconductor module from cross-sectional side-view perspective; and FIG. 1B illustrates the power semiconductor module from a cross-sectional plan-view perspective.

FIG. 2 illustrates a power semiconductor module from a cross-sectional side-view perspective, according to another embodiment.

FIG. 3, which includes FIGS. 3A and 3B, illustrates a power semiconductor module, according to an embodiment. FIG. 3A illustrates the power semiconductor module from cross-sectional side-view perspective; and FIG. 3B illustrates the power semiconductor module from a cross-sectional plan-view perspective.

FIG. 4, which includes FIGS. 4A and 4B, illustrates a power semiconductor module, according to an embodiment. FIG. 4A illustrates the power semiconductor module from cross-sectional side-view perspective; and FIG. 4B illustrates the power semiconductor module from a cross-sectional plan-view perspective.

FIG. 5 illustrates a power semiconductor module from a cross-sectional side-view perspective, according to another embodiment.

### DETAILED DESCRIPTION

A method and corresponding device are described herein that utilize the advantageous rapid energy transfer capability of inductive heating to expedite the curing of a potting compound within a semiconductor module. The semiconductor module comprises a housing that encloses an interior volume over a power electronics carrier with a power semiconductor die mounted thereon. The interior volume is filled with a potting compound that is used to encapsulate and protect the power semiconductor die and associated electrical connections. The power module assembly comprises inductive heatable particles disposed within a structure that is thermally coupled to the potting compound or within the potting compound itself. These inductive heatable particles are used to rapidly heat up the potting compound in order to accelerate chemical reactions such those causing curing of the potting compound and/or activating adhesion promoters in the potting compound. This greatly reduces the amount of time needed to cure the potting compound.

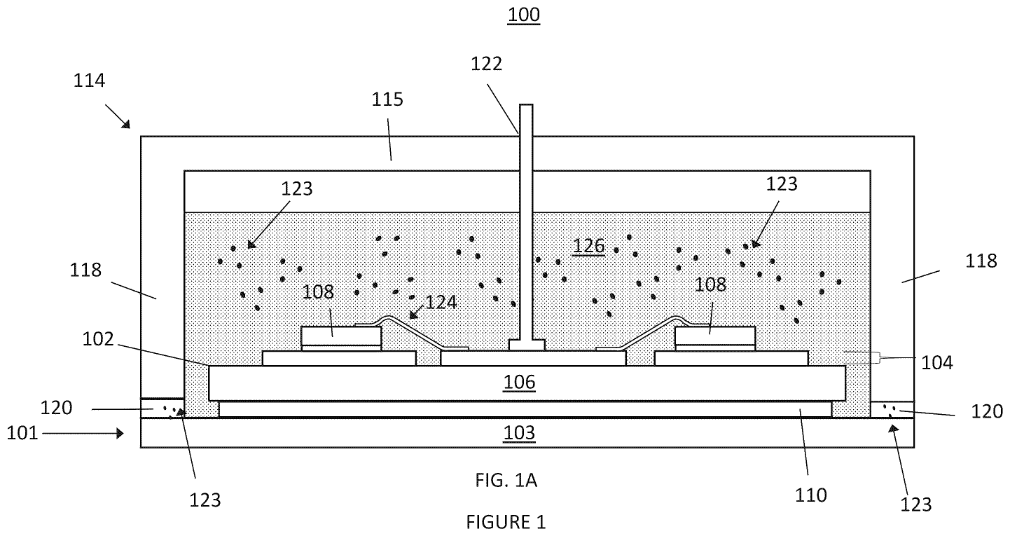

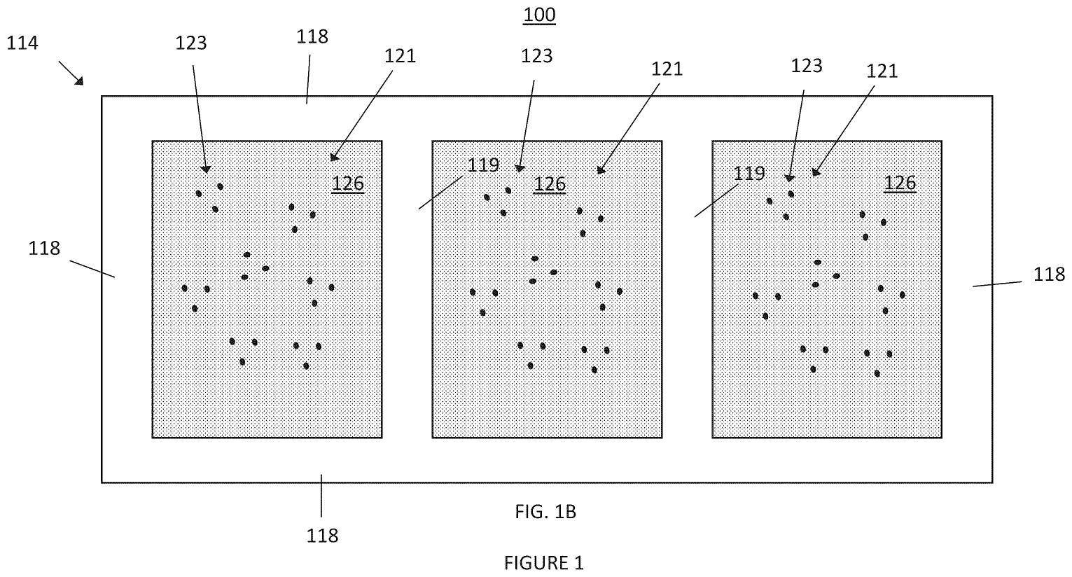

Referring to FIG. 1A, a semiconductor module 100 is depicted, according to an embodiment. The semiconductor module 100 comprises a floor section 101. In the embodiment of FIG. 1, semiconductor module 100 comprises a baseplate 103 that forms the floor section 101. This baseplate 103 may be formed from a thermally conductive material, such as a metal, e.g., copper, aluminum, alloys thereof, etc. The semiconductor module 100 comprises a housing 114 that encloses an interior volume over the floor section 101. The housing 114 comprises outer sidewalls 118 that are affixed to the floor section 101 by a glue 120. The glue 120 may be any kind of electronics adhesive, including polymer-based electronics glue. The sidewalls 118 may, of course, by affixed to the floor section 101 by other conventional methods, such as through use of mechanical fasteners and sealing rings. The housing 114 may comprise a lid 115 that extends over the interior volume thus allowing for the housing 114 to form a complete seal of the interior volume. The lid 115 and the outer sidewalls 118 may be integrally formed components of the same structure (as shown). Alternatively, the lid 115 may be a separate structure that is attachable to and from the outer sidewalls 118.

The semiconductor module 100 further comprises a power electronics carrier 102 within the interior volume. The power electronics carrier 102 comprises a structured metallization layer 104 disposed on an electrically insulating substrate 106. The structured metallization layer 104 comprises a plurality of pads that are disposed on the electrically insulating substrate 106 and are electrically isolated from one another. The pads are dimensioned to accommodate the mounting of semiconductor dies 108 or passive elements thereon. Additionally, the pads can form part of an electrical interconnect structure that connects two or more devices together. The power electronics carrier 102 additionally comprises a second metallization layer 110 disposed on a rear side of the electronics power electronics carrier 102. The first structured metallization layer 104 and the second metallization layer 110 may comprise or be plated with any or more of Al, Cu, Ni, Ag, Au, Pd, Pt, NiV, NiP, NiNiP, NiP/Pd, Ni/Au, NiP/Pd/Au, or NiP/Pd/AuAg. The second metallization layer 110 may be attached to the floor section 101 by an adhesive, solder, sinter, etc. The semiconductor module 100 can be mounted on a cooling apparatus, such as a heat sink, wherein the power electronics carrier 102 and the floor section 101 collectively draw heat away from the power semiconductor dies 108.

According to embodiments, the power electronics carrier 102 is a Direct Copper Bonding (DCB) substrate, a Direct Aluminum Bonding (DAB) substrate, or an Active Metal Brazing (AMB) substrate. The electrically insulating substrate 106 for each of these types of carriers may comprise a ceramic material such as Al₂O₃ (Alumina) AlN (Aluminium Nitride), etc. According to another embodiment, the power electronics carrier 102 is Insulated Metal Substrate (IMS). The electrically insulating substrate 106 for an IMS substrate may comprise filled materials such as epoxy resin or polyimide. According to another embodiment, the power electronics carrier 102 is a printed circuit board (PCB). In that case, the electrically insulating substrate 106 may comprise a resin material such as FR-4.

The semiconductor module 100 comprises one or more power semiconductor dies 108 mounted on the power electronics carrier 102 within the interior volume. The power semiconductor dies 108 may be mechanically attached and (optionally) electrically connected to the structured pads of the structured metallization layer 104 by a conductive adhesive, e.g., solder, sinter, conductive glue, etc. The term power semiconductor die 108 refers to a single device that is rated to accommodate voltages of at least 100 V (volts), and more typically voltages of 600 V, 1200 V, 1700 V, 3300 V, 6500 V or more and/or is rated to accommodate currents of at least 1 A, and more typically currents of 10 A, 50 A, 100 A, 200 A or more. Examples of power semiconductor dies 108 include discrete power diodes and discrete power transistor dies, e.g., MOSFETs (Metal Oxide Semiconductor Field Effect Transistors), IGBTs (Insulated Gate Bipolar Transistors), and HEMTs (High Electron Mobility Transistors), etc. Separately or in combination, other types of devices, e.g., logic devices, custom circuits, controllers, sensing devices, passive elements, etc. may be mounted on the power electronics carrier 102.

According to an embodiment, the semiconductor module 100 is configured as a power converter or power inverter. For example, semiconductor module 100 may comprise one or more half-bridge circuits, wherein the power semiconductor dies 108 may be power transistors that form the high-side switch and low-side switch of this half-bridge circuit. The semiconductor module 100 may additionally comprise one or more driver dies that control a switching operation of the half-bridge circuit.

The semiconductor module 100 may comprise terminals 122 that extend through the housing 114 and are externally accessible from an upper side of the semiconductor module 100. The terminals 122 are electrically conductive structures that form external points of electrical contact to the devices contained within the interior volume. The terminals 122 may be formed from an electrically conductive material, such as a metal, e.g., copper, aluminum, alloys thereof, etc. The terminals 122 may be disposed in different locations. For example, in other embodiments, the terminals 122 may be anchored within the outer sidewalls 118 of the housing 114. The terminals 122 may have a wide variety of geometric configurations. For example, at least some of the terminals 122 may be configured as press-fit connectors.

The semiconductor module 100 comprises electrical interconnect elements 124 that are used to effectuate an electrical interconnection between the power semiconductor dies 108 and the terminals 122. As shown, the electrical interconnect elements 124 are configured as conductive bond wires. These bond wires connect terminals of the semiconductor dies to the structured metallization layer 104 and connect the structured metallization layer 104 to the terminals 122. More generally, the electrical interconnect elements 124 can be any type of interconnect element, e.g., clips, ribbons, bond wires, flexible circuit boards, etc., that are attached to the devices and/or metal pads of the semiconductor module 100 using any known technique. Additionally, the semiconductor module 100 may comprise additional metal structures, such as tabs or busbar structures (not shown) that deliver fixed voltages to the various devices mounted on the on the power electronics carrier 102.

The interior volume of the semiconductor module 100 is filled with a potting compound 126. The potting compound 126 is an electrically insulating encapsulant material that protects power semiconductor dies 108, the electrical interconnect elements 124 and the power electronics carrier 102 and provides dielectric isolation of these elements. The potting compound 126 may comprise a matrix of epoxy resin, a plastic, or silicone-based gel, for example. The matrix may be blended with a networking agent, which helps to form a three-dimensional network of interconnected polymer chains during the curing process, giving the cured gel its structure and mechanical properties. The potting compound 126 is initially flowed into the interior volume in a liquified state and subsequently cured to cross-link the chemical bonds in the polymer with the networking agent. The curing process requires time and may comprise a heating step to accelerate the cross-linking reaction.

According to an embodiment, the potting compound 126 comprises an adhesion promoter or an adhesion promoter system. The adhesion promoter is used to enhance adhesion with the interior surfaces of the semiconductor module 100, e.g., the power electronics carrier 102, the power semiconductor dies 108, the housing, etc. The adhesion promoter is an additive that is intermixed with the polymer matrix of the potting compound. The adhesion promoter may comprise a silane with functional groups, a polymer or an organo-metallic compound, for example, but may of course comprise other materials or a combination of different materials to connect the interior semiconductor module surfaces with the potting compound. The adhesion promoter may represent no more than one percent of the potting compound 126 by volume, for example. The adhesion reaction is activated and/or accelerated by heating the inductive heatable particles. The adhesion promoter may be activated by the same curing process that hardens the potting compound 126.

The semiconductor module 100 comprises inductive heatable particles 123. The inductive heatable particles 123 are electrically conductive particles that can be heated by using an inductive heating process. Inductive heating refers to a well-known technique whereby an electrical conductor is subjected to a time-varying magnetic field to produce eddy currents in the electrical conductor, which in turn induces heat through joule heating and magnetic hysteresis of the materials. While this technique can be used to heat all electrical conductors, certain materials are particularly well-suited for inductive heating. To this end, the inductive heatable particles 123 may comprise a magnetic material, such as a ferromagnetic, ferrimagnetic or a superparamagnetic material. Examples of ferromagnetic materials are iron, cobalt, nickel and their alloys or oxides. Ferrimagnetic materials are ferrites, i.e., compositions of iron oxides such as Fe₂O₃ and Fe₃O₄. Superparamagnetic particles are a type of nanoparticle that exhibit magnetic properties when placed in a magnetic field, but lose those properties when the magnetic field is removed. These particles are typically composed of ferromagnetic or ferrimagnetic materials, and typically have a size in the range of a few nanometers to a hundred nanometers. The inductive heatable particles 123 may also comprise a coating of an electrically insulating material, e.g., SiO₂.

In the embodiment of FIG. 1, the inductive heatable particles 123 are incorporated into the potting compound 126. The inductive heatable particles 123 may be dispersed throughout the volume of the potting compound 126 in a homogenous or quasi-homogeneous distribution. The amount of inductive heatable particles 123 can be any amount that maintains the electrically insulating properties of the potting compound 126. That is, the percent volume of the inductive heatable particles 123 may be selected to be below a percolation threshold of the potting compound 126. For example, the potting compound 126 may comprise up to 16 percent by volume of the inductive heatable particles 123, or even higher in some cases. The potting compound may comprise as low as 0.01% by volume of the inductive heatable particles, or even lower, especially if superparamagnetic particles are used.

According to an embodiment, the inductive heatable particles 123 are used as part of a glue curing process that heats the glue 120. That is, the glue is cured by inductively heating the inductive heatable particles 123. Similar to the potting compound 126, the glue curing process may require a combination of time and temperature to cause cross-linking of the polymers and form a stable, secure bond. This avoids the need for other types of glue curing steps such as providing a circulating air oven and/or a hot plate underneath the floor section 101 and/or applying infrared light.

According to the depicted embodiment, the inductive heatable particles 123 are incorporated into the glue 120 itself. Thus, the inductive heatable particles 123 can be used to directly heat the glue 120. Alternatively, the inductive heatable particles 123 can be provided within another element that thermally coupled to the glue 120.

According to an embodiment, an inductive heatable plate is thermally coupled to the potting compound 126 and the curing process comprises inductively heating the inductive heatable plate and the inductive heatable particles 123. That is, the combination of the inductive heatable particles 123 and a separate inductive heatable plate are used together to quickly cure the potting compound. In the embodiment of FIG. 1, the inductive heatable plate can correspond to the substrate or baseplate 103 which forms the floor section 101. For example, the baseplate 103 can comprise iron and/or ferrimagnetic material. The plate may also be coated with inductive heatable materials such as those from which the inductive heatable particles are composed.

Referring to FIG. 1B, the housing 114 may be configured with interior walls 119 that divide the interior volume into a plurality of compartments 121. The interior walls 119 may each be glued to the floor section, with one of the assemblies comprising a power electronics carrier 102 and power semiconductor dies 108 mounted thereon contained within each compartment 121. Each of the compartments 121 may comprise a volume of the potting compound 126 with the inductive heatable particles 123 intermixed therein.

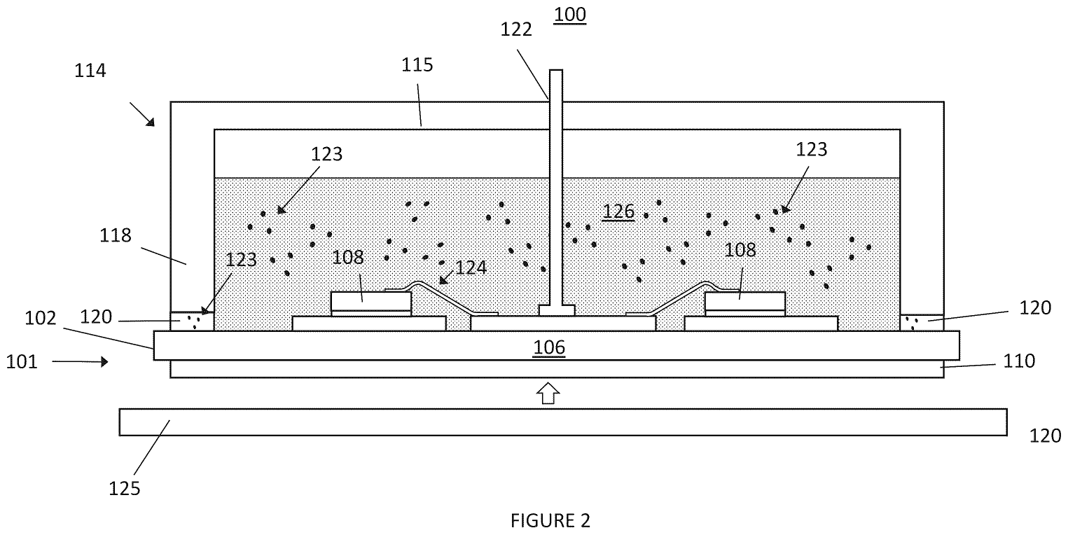

Referring to FIG. 2, the semiconductor module 100 is shown, according to another embodiment. This embodiment is substantially similar to that of FIG. 1, except that the power electronics carrier 102 forms the floor section 101 of the semiconductor module 100. That is, the metal baseplate 103 is omitted and the housing 118 is glued directly to the power electronics carrier 102. In an embodiment wherein a separate inductive heatable plate is used together with the inductive heatable particles 123 to heat the adhesion promoter to its activation temperature, this inductive heatable plate can be provided by a separate carrier 125 that is brought into contact with the floor section 101. This carrier 125 can comprise iron and/or ferrimagnetic material. This separate carrier 125 may be needed if the power electronics carrier 102 itself is a commercially available device that cannot be configured as an inductive heatable structure.

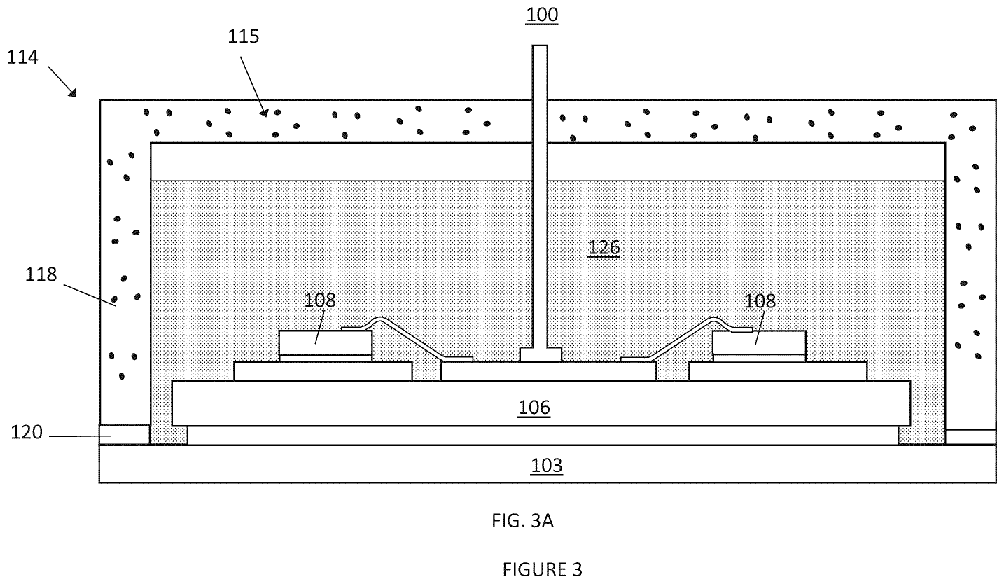

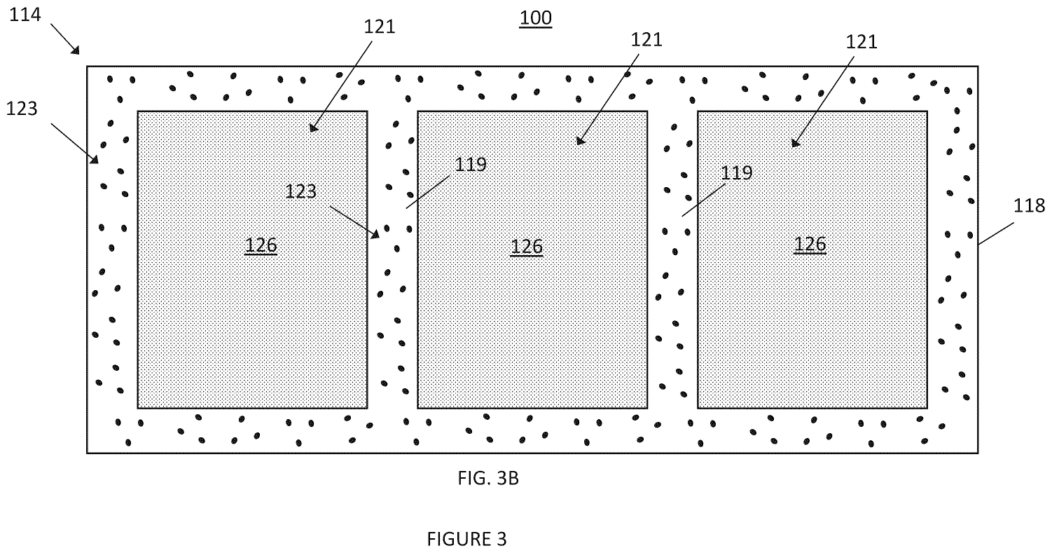

Referring to FIG. 3A, the semiconductor module 100 is shown, according to another embodiment. In this embodiment, the inductive heatable particles 123 are provided within the housing 114. Thus, in a difference to the previously described embodiments, the inductive heatable particles 123 are provided outside of the potting compound 126. In this case, the plastic material that forms the outer sidewalls 118 comprises the inductive heatable particles 123 incorporated therein. The inductive heatable particles 123 may be provided in a homogenous or quasi-homogeneous distribution throughout this plastic material. In a similar manner as described above, the percentage of inductive heatable particles 123 can be any amount up to a percolation threshold of the material such that the housing 114 remains as an electrical insulator. As shown, the inductive heatable particles 123 may be provided throughout the housing 114. Alternatively, the inductive heatable particles 123 may be omitted from the lid portion 115 and only provided within in the outer sidewalls 118. The inductive heatable particles 123 within the housing 114 may be inductively heated as described above, except the heat is transferred to the potting compound 126 via the housing 114.

Referring to FIG. 3B, the housing 114 may be configured such that the outer sidewalls 118 and each of the interior walls 119 comprises the inductive heatable particles 123 incorporated therein. This arrangement provides the inductive heatable particles 123 surrounding each of the compartments 121. In this way, the source of inductive heating is interleaved throughout the potting compound 126. As the potting compound 126 is a thermal insulator, this arrangement allows for quicker and more uniform heating of the material.

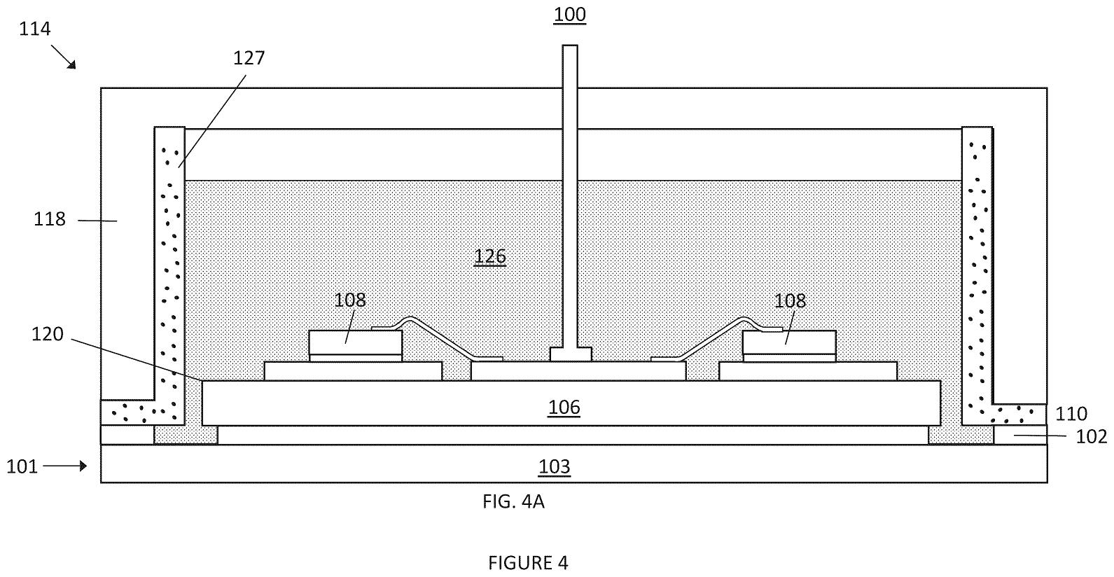

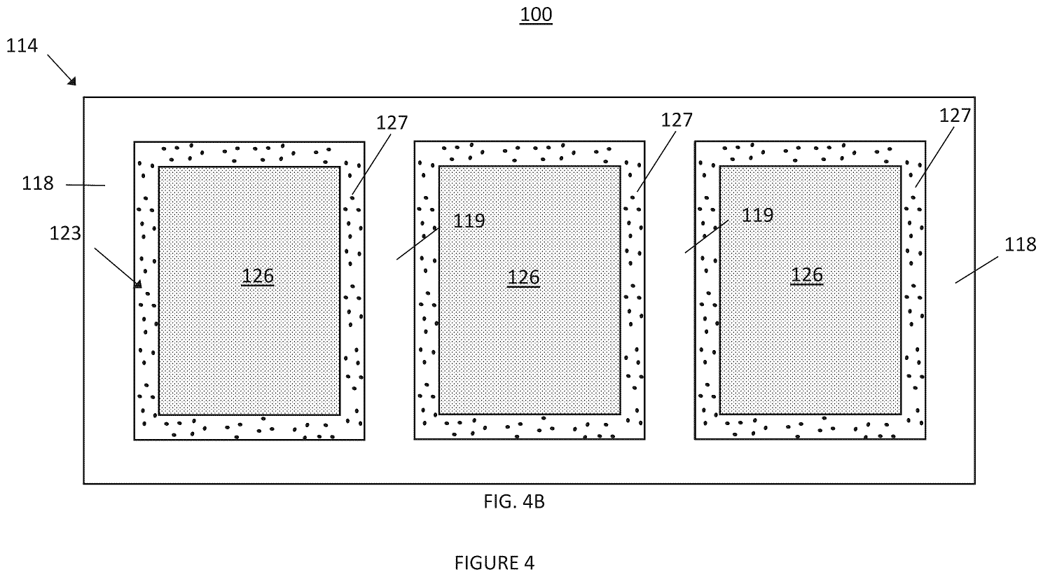

Referring to FIG. 4A, the semiconductor module 100 is shown, according to another embodiment. In this embodiment, the semiconductor module 100 comprises a passive heatable structure 127 that is arranged along an inside surface of the housing 114 and comprises the inductive heatable particles 123. The housing 114 itself may be a plastic structure that is devoid of the inductive heatable particles 123. The passive heatable structure 127 may comprise an electrically insulating base material, e.g., plastic, rubber, epoxide, glass, etc., with the inductive heatable particles 123 provided in a homogenous or quasi-homogeneous distribution throughout this material. In a similar manner as described above, the percentage of inductive heatable particles 123 can be any amount up to a percolation threshold of the material such that the passive heatable structure 127 remains as an electrical insulator. According to an embodiment, the passive heatable structure 127 is a molded structure that is formed by a molding technique, e.g., injection molding, compression molding, transfer molding, etc. The inductive heatable particles 123 may be dispersed throughout the polymer matrix of the mold compound that forms this molded structure.

The passive heatable structure 127 may be affixed to the housing 114 in any of a number of different ways. For example, it may be molded directly onto the housing 114 through a 2K, or two-shot injection process. In this process, the housing 114 would likely be injection molded first, and then the passive heatable structure 127 would be injection molded in cavities of a mold containing the fully molded housing 114. Of course, the passive heatable structure 127 may also be molded separately and then later affixed to the housing 114, e.g., using an adhesive.

Referring to FIG. 4B, the passive heatable structure 127 may be provided along each of the outer sidewalls 118 and each of the interior walls 119. This arrangement provides the inductive heatable particles 123 surrounding each of the compartments 121 in a similar manner as described above.

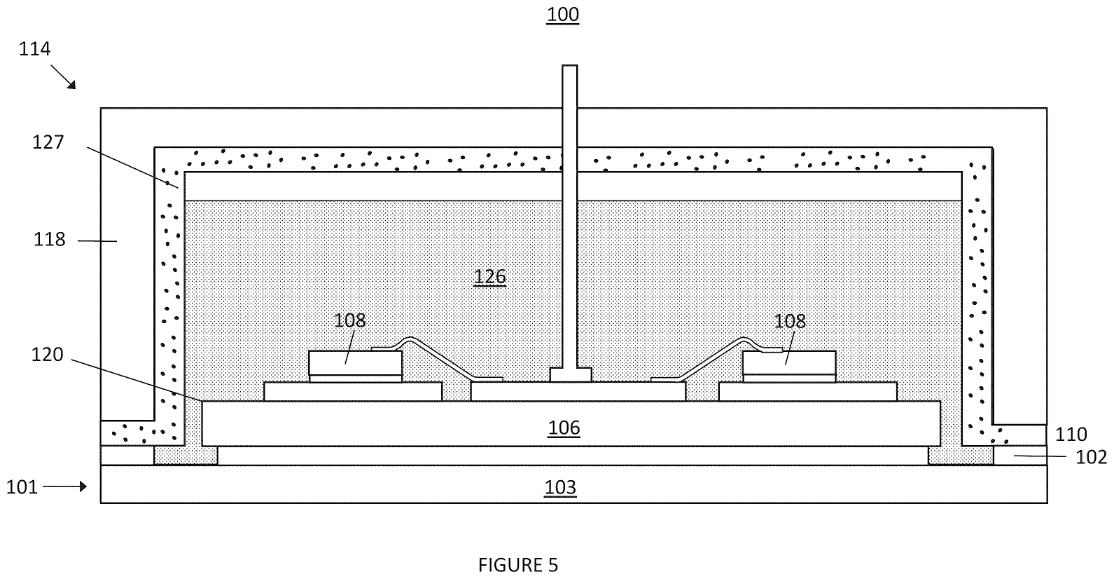

Referring to FIG. 5, the semiconductor module 100 is shown, according to another embodiment. In this embodiment, the semiconductor module 100 comprises the passive heatable structure 127 that is arranged along an inside surface of the housing 114 and comprises the inductive heatable particles 123. In this case, the passive heatable structure 127 is arranged as a layer of material that lines all or parts of the inside surface of the housing 114. There may be portions of the housing 114 which should not be covered by the passive heatable structure 127, for example, where there are terminals that have to be welded or soldered. The coating could also be applied to other parts of the module, as long as the coating does not interfere with operation of the module components. According to an embodiment, this layer is provided by spray coating the inside surface of the housing 114 with an electrically insulating material that comprises a concentration of the inductive heatable particles 123. In a similar manner as described above, the percentage of inductive heatable particles 123 can be any amount up to a percolation threshold of the material such that the passive heatable structure 127 remains as an electrical insulator.

Although the present disclosure is not so limited, the following numbered examples demonstrate one or more aspects of the disclosure.

Example 1. A method of producing a semiconductor module, the method comprising: providing a power module assembly that comprises a floor section, a housing that encloses an interior volume over the floor section, and a power semiconductor die mounted to a power electronics carrier within the interior volume; filling the interior volume with a potting compound; providing inductive heatable particles within the power module assembly; and inductively heating the inductive heatable particles to activate and/or accelerate a chemical reaction in the semiconductor module.

Example 2. The method of example 1, wherein the inductive heatable particles comprise magnetic particles.

Example 3. The method of example 1, further comprising providing an inductive heatable plate that is thermally coupled to the potting compound, wherein the inductive heatable plate comprises the inductive heatable particles.

Example 4. The method of example 3, wherein the inductive heatable plate is a baseplate that forms the floor section.

Example 5. The method of example 3, wherein the power electronics carrier forms the floor section, and wherein the inductive heatable plate is a carrier that is brought into contact with the floor section.

Example 6. The method of example 1, wherein providing the assembly comprises providing glue between outer sidewalls of the housing and the floor section, and wherein the method comprises performing a glue curing process that heats the glue, and wherein performing the glue curing process comprises inductively heating the inductive heatable particles to heat the glue.

Example 7. The method of example 6, wherein providing inductive heatable particles within the power module assembly comprises incorporating the inductive heatable particles into the glue.

Example 8. The method of example 1, wherein providing inductive heatable particles within the power module assembly comprises incorporating the inductive heatable particles into the potting compound, and the chemical reaction cures the potting compound.

Example 9. The method of example 1, wherein providing inductive heatable particles within the power module assembly comprises incorporating the inductive heatable particles into the potting compound, and the chemical reaction activates an adhesion promoter in the potting compound.

Example 10. The method of example 1, wherein providing inductive heatable particles within the power module assembly comprises incorporating the inductive heatable particles along or within the housing.

Example 11. The method of example 10, wherein the housing comprises interior walls that divide the interior volume into a plurality of compartments, and wherein incorporating the inductive heatable particles along or within the housing comprises incorporating the inductive heatable particles along or within the interior walls.

Example 12. The method of example 1, wherein incorporating the inductive heatable particles along or within the housing comprises forming a passive heatable structure that is arranged along an inside surface of the housing and comprises the inductive heatable particles.

Example 13. The method of example 10, wherein incorporating the inductive heatable particles along or within the housing comprises spray coating the inside surface of the housing with a material that comprises a concentration of the inductive heatable particles.

Example 14. The method of example 12, incorporating the inductive heatable particles along or within the housing comprises injection molding a structure that comprises a concentration of the inductive heatable particles.

Example 15. A semiconductor module, comprising: a floor section; a housing that encloses an interior volume over the floor section; a power semiconductor die mounted to a power electronics carrier within the interior volume; a potting compound within the interior volume; and inductive heatable particles, wherein the inductive heatable particles are either within the potting compound or are within a structure that is thermally coupled to the potting compound.

Example 16. The semiconductor module of example 15, wherein the inductive heatable particles comprise magnetic particles.

Example 17. The semiconductor module of example 16, wherein the magnetic nanoparticles comprise any one of the following: ferromagnetic particles, ferrimagnetic particles and superparamagnetic particles.

Example 18. The semiconductor module of example 15, further comprising an inductive heatable plate that is thermally coupled to the potting compound.

Example 19. The semiconductor module of example 15, wherein the inductive heatable particles are incorporated into the potting compound.

Example 20. The semiconductor module of example 15, wherein the inductive heatable particles are disposed along or within the housing.

The semiconductor dies disclosed herein can be formed in a wide variety of device technologies that utilize a wide variety of semiconductor materials. Examples of such materials include, but are not limited to, elementary semiconductor materials such as silicon (Si) or germanium (Ge), group IV compound semiconductor materials such as silicon carbide (SIC) or silicon germanium (SiGe), binary, ternary or quaternary III-V semiconductor materials such as gallium nitride (GaN), gallium arsenide (GaAs), gallium phosphide (GaP), indium phosphide (InP), indium gallium phosphide (InGaPa), aluminum gallium nitride (AlGaN), aluminum indium nitride (AlInN), indium gallium nitride (InGaN), aluminum gallium indium nitride (AlGaInN) or indium gallium arsenide phosphide (InGaAsP), etc.

The semiconductor dies disclosed herein may be configured as a vertical device, which refers to a device that conducts a load current between opposite facing main and rear surfaces of the die. Alternatively, the semiconductor dies may be configured as a lateral device, which refers to a device that conducts a load current parallel to a main surface of the die.

Spatially relative terms such as “under,” “below,” “lower,” “over,” “upper” and the like, are used for ease of description to explain the positioning of one element relative to a second element. These terms are intended to encompass different orientations of the device in addition to different orientations than those depicted in the figures. Further, terms such as “first,” “second,” and the like, are also used to describe various elements, regions, sections, etc. and are also not intended to be limiting. Like terms refer to like elements throughout the description.

As used herein, the terms “having,” “containing,” “including,” “comprising” and the like are open-ended terms that indicate the presence of stated elements or features, but do not preclude additional elements or features. The articles “a,” “an” and “the” are intended to include the plural as well as the singular, unless the context clearly indicates otherwise.

With the above range of variations and applications in mind, it should be understood that the present invention is not limited by the foregoing description, nor is it limited by the accompanying drawings. Instead, the present invention is limited only by the following examples and their legal equivalents.

What is claimed is:

1. A method of producing a semiconductor module, the method comprising:
providing a power module assembly that comprises a floor section, a housing that encloses an interior volume over the floor section, and a power semiconductor die mounted to a power electronics carrier within the interior volume;
filling the interior volume with a potting compound;
providing inductive heatable particles within the power module assembly; and
inductively heating the inductive heatable particles to activate and/or accelerate a chemical reaction in the semiconductor module.

2. The method of claim 1, wherein the inductive heatable particles comprise magnetic nanoparticles.

3. The method of claim 1, further comprising providing an inductive heatable plate that is thermally coupled to the potting compound, wherein the inductive heatable plate comprises the inductive heatable particles.

4. The method of claim 3, wherein the inductive heatable plate is a metal baseplate that forms the floor section.

5. The method of claim 3, wherein the power electronics carrier forms the floor section, and wherein the inductive heatable plate is a carrier that is brought into contact with the floor section.

6. The method of claim 1, wherein providing the power module assembly comprises providing glue between outer sidewalls of the housing and the floor section, and wherein the chemical reaction accelerates curing of the glue.

7. The method of claim 6, wherein providing inductive heatable particles within the power module assembly comprises incorporating the inductive heatable particles into the glue.

8. The method of claim 1, wherein providing inductive heatable particles within the power module assembly comprises incorporating the inductive heatable particles into the potting compound, and the chemical reaction cures the potting compound.

9. The method of claim 1, wherein providing inductive heatable particles within the power module assembly comprises incorporating the inductive heatable particles into the potting compound, and the chemical reaction activates an adhesion promoter in the potting compound.

10. The method of claim 1, wherein providing inductive heatable particles within the power module assembly comprises incorporating the inductive heatable particles along or within the housing.

11. The method of claim 10, wherein the housing comprises interior walls that divide the interior volume into a plurality of compartments, and wherein incorporating the inductive heatable particles along or within the housing comprises incorporating the inductive heatable particles along or within the interior walls.

12. The method of claim 1, wherein incorporating the inductive heatable particles along or within the housing comprises forming a passive heatable structure that is arranged along an inside surface of the housing and comprises the inductive heatable particles.

13. The method of claim 12, wherein incorporating the inductive heatable particles along or within the housing comprises spray coating the inside surface of the housing with a material that comprises a concentration of the inductive heatable particles.

14. The method of claim 12, incorporating the inductive heatable particles along or within the housing comprises injection molding a structure that comprises a concentration of the inductive heatable particles.

15. A semiconductor module, comprising:
a floor section;
a housing that encloses an interior volume over the floor section;
a power semiconductor die mounted to a power electronics carrier within the interior volume;
a potting compound within the interior volume; and
inductive heatable particles,
wherein the inductive heatable particles are either within the potting compound or are within a structure that is thermally coupled to the potting compound.

16. The semiconductor module of claim 15, wherein the inductive heatable particles comprise magnetic particles.

17. The semiconductor module of claim 16, wherein the magnetic particles comprise any one of the following:
ferromagnetic particles;
ferrimagnetic particles; and
superparamagnetic particles.

18. The semiconductor module of claim 15, further comprising an inductive heatable plate that is thermally coupled to the potting compound.

19. The semiconductor module of claim 15, wherein the inductive heatable particles are incorporated into the potting compound.

20. The semiconductor module of claim 15, wherein the inductive heatable particles are disposed along or within the housing.
